(19) United States
(12) Patent Application Publication
(10) Pub. No.: US 2007/0132352 A1
(43) Pub. Date: Jun. 14, 2007

(54) Electrical luminescence foil and method for producing same

(76) Inventor: Thorsten Fink, Albershausen (DE)

Correspondence Address: CLARK HILL, P.C., 500 WOODWARD AVENUE, SUITE 3500, DETROIT, MI, 48226, US

(21) Appl. No.: 11/521,742

(22) Filed: Sep. 15, 2006

(30) Foreign Application Priority Data
Sep. 15, 2005 (DE) 10 2005 045 693.6

(51) Int. Cl. H05B 33/00; H01L 51/50

(52) U.S. Cl. 313/112; 428/917; 257/98

(57) ABSTRACT

An electroluminescent film includes a base film through which an electric current is selectively passed. The base film emits radiant energy in the visible spectrum when the electric current is passed therethrough. A filter layer is fixedly secured to the base film and filters a portion of the radiant energy wherein only a portion of the radiant energy emitted by the base film passes through the filter layer to be visible to an observer.

### BACKGROUND ART

1. Field of the Invention

The invention relates to an electroluminescent film for emitting light. More particularly, the invention relates to an electroluminescent film for emitting light of varying wavelengths and a method for its production.

2. Description of the Related Art

Electroluminescent films are generally two-dimensional illuminants that radiate light when subjected to electric current. The electroluminescent film has a base film in which fluorescing substances are present. As a rule, the fluorescing substance is a zinc sulfide (phosphor powder). The portion of the spectrum of the electromagnetic radiation, i.e., the hue of the light, radiated by the electroluminescent film depends on the doping of the fluorescing pigments. If the electroluminescent films must be prepared for differing hues of radiated light, production is worthwhile only for large quantities. Not all color locations or hues can be realized through varying doping of the phosphor powder. Also, the yield of the luminance is often only slight.

Electroluminescent films are also known in which the particular portion of the electromagnetic radiation spectrum is adjusted through the addition of fluorescing coloring agents into the phosphor paste. Thus, for example, the reflected light color (when the electroluminescent film is not switched on) can be pink, while the electroluminescent film radiates white when it is switched on. As a result of the added coloring agent, however, the reflected light color of the electroluminescent film, i.e., the hue of this film when it is not electrified, changes. Frequently, however, a neutral reflected light color is required in the switched-off state, so that the addition of fluorescing coloring agents is not possible. In addition, there is the problem of separation of the coloring agent within the phosphor paste so that the quality of the electroluminescent film is impaired. There is also the problem of UV resistance of the coloring agent or pigment.

The object of the invention is to configure the generic electroluminescent film and the method for producing it such that with simple production, all hues of the light to be radiated from the electroluminescent film can be set and a long useful light and high luminescence are ensured.

This object is solved in the generic electroluminescent film according to the invention with the characterizing features of claim 1 and in the generic method according to the invention with the characterizing features of claim 11.

In the electroluminescent film according to the invention, the light, which as a rule has a hue, radiated from the base film passes through the color filter layer. With it, any desired color can be produced which is desired for the application of the electroluminescent film. Thus the electroluminescent film according to the invention by way of example has a useful life of around 10,000 hours with a green illuminating color and up to around 3,000 hours with a red illuminating color. In addition, the electroluminescent film according to the invention is characterized by a high luminance.

In the method according to the invention, the color filter layer is initially imprinted onto the carrier film. Following this, the unit composed of color filter layer and carrier film is attached to the base film.

Advantageously the color filter layer contains fluorescing pigments imbedded in a binding agent. The color filter layer thus forms a fluorescent filter with which the desired hue of the radiated light can be set. Depending of the desired color location, various fluorescing pigments are added to the binding agent.

The color filter layer preferably is provided on a carrier film so that the base film remains unchanged. The carrier film with the color filter layer is merely fastened onto it.

The carrier film advantageously is composed of polyester.

In order to achieve optimal protection of the electroluminescent film, it advantageously is backed.

The side of the carrier film next to the color filter layer is advantageously provided with a layer that determines the reflected light color of the electroluminescent film. Advantageously this layer consists of white fluorescent color. Then the electroluminescent film in switched-off condition has a neutral, whitish hue. It of course is possible to configure this layer such that the electroluminescent film in switched-off condition has a hue. In this case, fluorescing pigment particles are contained in this layer.

The fluorescing pigments advantageously are uniformly distributed in the color filter layer so that the light radiated from the electroluminescent film has a uniform luminance.

But it is also possible for the fluorescing pigments to arranged so as to be not uniformly distributed in the color filter layer. Then a gradient of light intensity can be set.

### SUMMARY OF THE INVENTION

An electroluminescent film includes a base film through which an electric current is selectively passed. The base film emits radiant energy in the visible spectrum when the electric current is passed therethrough. A filter layer is fixedly secured to the base film and filters a portion of the radiant energy wherein only a portion of the radiant energy emitted by the base film passes through the filter layer to be visible to an observer.

### BRIEF DESCRIPTION OF THE DRAWINGS

Advantages of the invention will be readily appreciated as the same becomes better understood by reference to the following detailed description when considered in connection with the accompanying drawings, wherein:

FIG. 1 is a schematic sectional side view of an electroluminescent film according to the invention;

FIG. 2 is a schematic side view of various layers of the electroluminescent film; and

FIG. 3 is an exploded view the various layers of the electroluminescent film according to the invention.

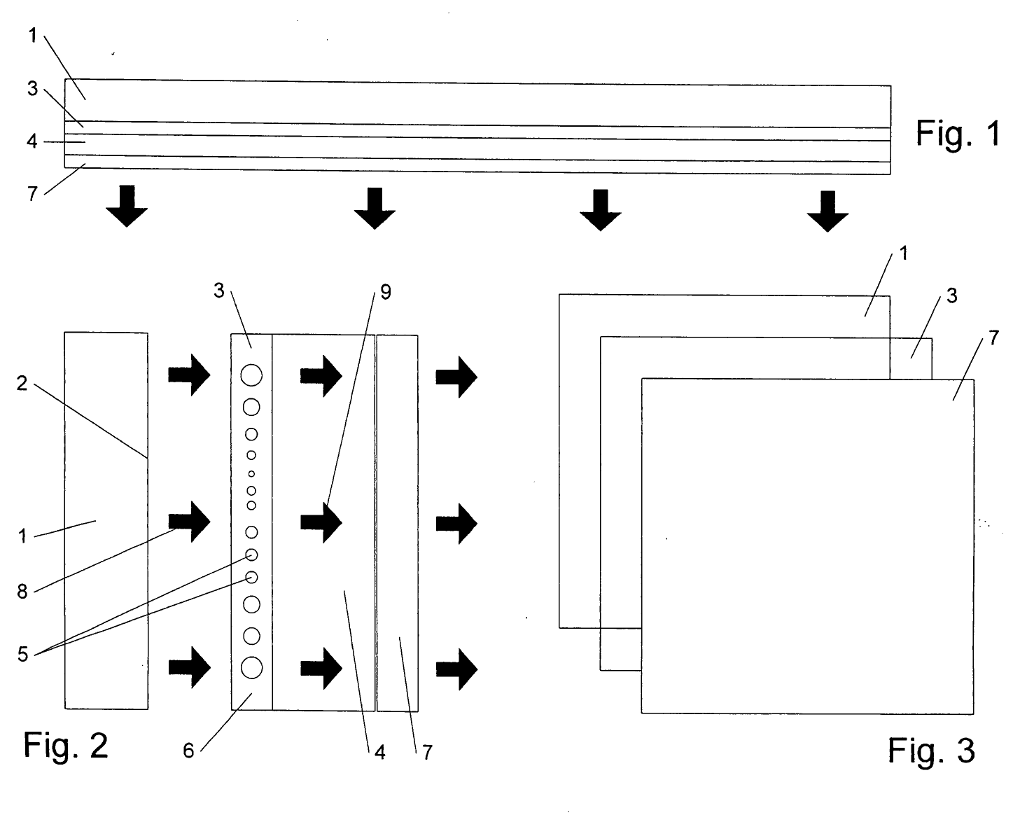

### DETAILED DESCRIPTION OF THE PREFERRED EMBODIMENT

The electroluminescent film forms a two-dimensional illuminant that depending on configuration can radiate light in varying hues. Such electroluminescent films are advantageously utilized in the automobile industry, for example in the interior of an automobile. Thus electroluminescent films can be used in the headliner, as marking lights at door handles and the like.

The electroluminescent film has a base film 1 that in switched-on condition radiates light of a specific color, for example green light. In the installed position, this base film 1 forms the back side of the electroluminescent film. On the one side 2 of base film 1, there is a color filter 3 with which the desired hue of the light radiated from the electroluminescent film can be set. The color filter 3 is situated on the one side of a carrier film 4 that covers the color filter 3. It contains fluorescing pigments 5 that are embedded in a binding agent 6. The proportion of pigment 5 to binding agent 6 is selected depending on the desired color saturation.

The color filter 3 is applied to carrier film 4 in a printing process. The printer or developer can adapt the hue on site to the desires of the customer. As a result, it is possible to very quickly fulfill the desires of the customer with respect to the hue of the electrified electroluminescent film. During the printing process, it is possible to directly influence the hue. Since the printing process can be well controlled, the amount of scrap is very low in the production of this electroluminescent film: In the printing process, the color pigments can be optimally arranged. Thus, for example, a uniform coverage of the surface of carrier film 4 with fluorescing pigments 5 is possible. But color gradients can also be easily and reliably created in the printing process. Depending on the wishes of the customer, the color gradients can be extremely varied and/or have areas of translucence.

The color filter 3 can also be bonded to carrier film 4 through lamination. The carrier film 4 consists of a material that ensures an optimal bond with the fluorescing pigments 5 and/or the binding agent 6. By way of example, the carrier film 4 may be fabricated from polyester. But, it can also consist of any other transparent material that ensures a bond of pigments 5 and binding agent 6.

On the side facing the color filter 3, the carrier film 4 is provided with a fluorescing layer 7 that is more or less highly pigmented. In the exemplary embodiment, this fluorescing layer 7 is configured white, i.e., achromatic so that the light escaping to the outside through the layer 7 is not changed in its hue. If no current is passing through the electroluminescent film, as a result of layer 7 it has a white hue on its outside. In this case, the so-called reflected light color of the of the electroluminescent film is white. The layer 7 advantageously is applied to the carrier film 4 in the screen printing process.

Depending on the type of application, the fluorescing layer 7 can of course have a hue. In this embodiment, the electroluminescent film in non-electrified state reflects a particular color. Examples of possible reflected colors include, but are not limited to, yellow, blue or orange hues. The electroluminescent film then of course will have a corresponding luminescent color. In the described exemplary embodiment, the achromatic, white fluorescent color of the layer 7 does not have any influence or has only a negligible influence on the hue of the electroluminescent film in electrified condition.

In order that the electroluminescent film be optimally protected and in particular that it also have a high degree of stability in the presence of moisture, it is coated with a moisture-impervious laminate (not shown) so that the electroluminescent film will have a long useful life even under harsh operating conditions.

The carrier film 4 with imprinted color filter 3 is fastened in known manner to the upper side 2 of base film 1.

When electrified, the base film 1 emits light 8 corresponding to its hue (FIG. 2), which light penetrates the color filter 3. Corresponding to the fluorescing pigments 5 in the color filter 3, the hue is changed after passing through the color filter 3. Thus, the green hue of the light 8 originating from base film 1 can, by way of example, take on an orange hue after passing through the color filter 3. Upon the light beams 9 passing through the carrier film 4 and layer 7, the hue is not changed, so that the light in the hue determined by the color filter 3 emerges through the layer 7.

In the color filter 3, fluorescing particles of the most varied kinds can be provided such that all luminescent colors can be set. It is even possible to use fluorescing pigments of different colors within zones of color filter 3 so that light of different colors emerges through the layer 7. By means of the printing process, the distribution of the variously colored fluorescing pigment 5 in the color filter 3 can be produced very precisely and in the most varied of forms. In addition, it is possible to provide a color filter 3 only in areas on carrier film 4 so that it does not cover the entire exterior side of the carrier film.

The color filter 3 absorbs a portion of the light 1 radiated by base film 1 and permits the remainder of the light to pass through as remainder light 9.

All suitable pigments can be used as fluorescing pigments for the color filter 3 and the layer 7. All suitable binding agents can be used to bind the pigments. However, they must not have any influence on the pigment quality.

Depending on the desired color density, the percentage of pigment and binding agent in the electroluminescent film is between around 10% and around 70%.

The invention has been described in an illustrative manner. It is to be understood that the terminology, which has been used, is intended to be in the nature of words of description rather than of limitation.

Many modifications and variations of the invention are possible in light of the above teachings. Therefore, within the scope of the appended claims, the invention may be practiced other than as specifically described.

1-13. (canceled)

14. An electroluminescent film comprising:
a base film through which an electric current is selectively passed such that said base film emits radiant energy in the visible spectrum; and
a filter layer fixedly secured to said base film for filter a portion of the radiant energy wherein only a portion of the radiant energy emitted by said base film passes through said filter layer to be visible to an observer.

15. An electroluminescent film as set forth in claim 14 wherein said filter layer filters color.

16. An electroluminescent film as set forth in claim 15 wherein said filter layer includes a binding agent.

17. An electroluminescent film as set forth in claim 16 wherein said filter layer includes fluorescing pigments in said binding agent.

18. An electroluminescent film as set forth in claim 17 wherein said filter layer includes a carrier layer.

19. An electroluminescent film as set forth in claim 18 wherein said carrier layer is fabricated from polyester.

20. An electroluminescent film as set forth in claim 19 including a backing to support said electroluminescent film.

21. An electroluminescent film as set forth in claim 20 wherein said carrier layer defines an outer surface.

22. An electroluminescent film as set forth in claim 21 wherein said outer surface is reflective such that said outer surface reflects a specific color.

23. An electroluminescent film as set forth in claim 22 wherein said filter layer includes a fluorescing layer of fluorescing pigments.

24. An electroluminescent film as set forth in claim 23 wherein said fluorescing pigments are arranged in said filter layer such that a gradient results.

25. An electroluminescent film as set forth in claim 23 wherein said fluorescing pigments are uniformly distributed in said filter layer.
